(19) United States
(12) Patent Application Publication
(10) Pub. No.: US 2026/0223430 A1
(43) Pub. Date: Jul. 30, 2026

(54) INTERFACIAL LAYER BETWEEN CHANNELS AND INNER SPACERS FOR PERFORMANCE BOOST OF NANOSTRUCTURE TRANSISTORS

(71) Applicant: Taiwan Semiconductor Manufacturing Co., Ltd., Hsinchu (TW)

(72) Inventors: Chung-Yu LIN, Hsinchu (TW); Chang-Yun CHANG, Hsinchu (TW); Yen-Ting CHEN, Hsinchu (TW)

(73) Assignee: Taiwan Semiconductor Manufacturing Co., Ltd., Hsinchu (TW)

(21) Appl. No.: 19/038,287

(22) Filed: Jan. 27, 2025

(51) Int. Cl. H10D 64/68; H10D 30/00; H10D 30/01; H10D 30/43; H10D 62/10; H10D 62/13; H10D 64/66; H10D 84/01; H10D 84/83

(52) U.S. Cl. CPC H10D 64/685; H10D 30/014; H10D 30/0191; H10D 30/43; H10D 30/503; H10D 62/121; H10D 62/151; H10D 64/666; H10D 64/669; H10D 84/0128; H10D 84/0144; H10D 84/832

(57) ABSTRACT

A method for forming an integrated circuit includes forming a plurality of stacked channels of a transistor and forming a plurality of interfacial dielectric structures each in contact with one of the channels. The method includes forming a plurality of inner spacers interleaved with the channels. The method includes forming a gate metal wrapped around the channels.

After forming the gate metal, each inner spacer is in contact with a respective interfacial dielectric structure positioned between the inner spacer and an adjacent channel of the plurality of channels.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-18B are cross-sectional and top views of an integrated circuit at various stages of processing, in accordance with some embodiments.

FIG. 19 is a flow diagram of a method of manufacturing an integrated circuit, in accordance with some embodiments.

FIG. 20 is a flow diagram of a method of manufacturing an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,”. “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the disclosure provide a method for forming nanostructure transistors with reduced damage to the nanostructures/channels of the transistors during final release of the channels. The stacked channels of nanostructure transistors are initially interleaved with sacrificial semiconductor nanostructures. After formation of source/drain trenches, the sacrificial semiconductor nanostructures are removed and replaced with sacrificial dielectric nanostructures, also termed disposable oxide interposers. Embodiments of the present disclosure form an interfacial dielectric layer on the exposed channels after removal of the sacrificial semiconductor nanostructures and prior to formation of the sacrificial dielectric nanostructures. Eventually, the sacrificial dielectric nanostructures and the central portions of the interfacial dielectric layer are removed and replaced with gate metals/gate dielectrics. However, in the intervening time, the interfacial dielectric layer helps protect the channels from diffusion of unwanted atoms such as germanium, oxygen, source/drain dopants. Furthermore, the presence of the interfacial dielectric layer helps prevent shorting between gate metals and source/drain regions and the formation of the parasitic resistances.

Usage of the interfacial dielectric layer results in channels with reduced surface roughness, improved mobility, and reduced impurities. Usage of the interfacial dielectric structures results in channels with reduced resistance an improvement in Rp, which corresponds to the total resistance minus the channel resistance. Usage of the interfacial dielectric layer results in reduced risk of short circuits between gate metals and source/drain regions and reduction in parasitic resistance. This further results in transistors having superior electrical characteristics and better overall performance. This can improve wafer yields and overall function of integrated circuits and electronic devices in which the integrated circuits are embedded.

While the figures and description focus primarily on examples in which the transistors are nanostructure transistors including stacks of channels, principles of the present disclosure extend to other types of transistors. Principles of the present disclosure extend to MOS transistors, FinFET transistors and other types of transistors.

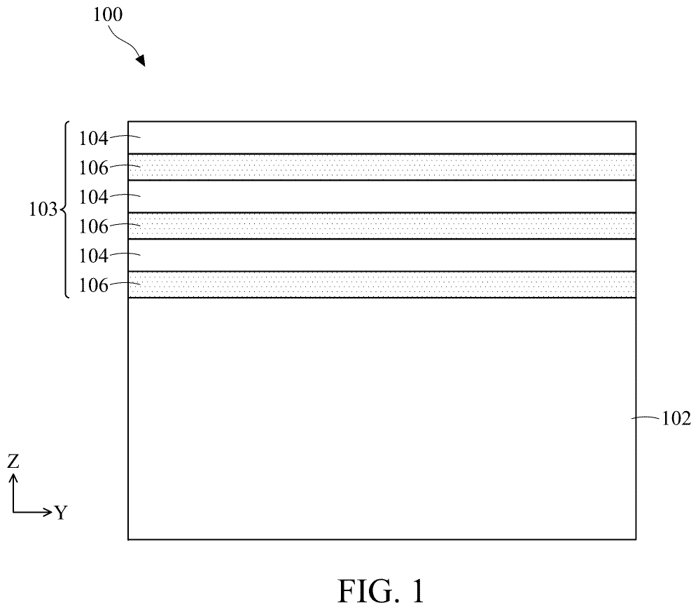

FIGS. 1-17 are cross-sectional views of an integrated circuit 100 fabricated in accordance with some embodiments of the present disclosure. The fabrication process results in a plurality of transistors, as will be described in further detail below.

FIG. 1 is a cross-sectional view of the integrated circuit 100 at an intermediate stage of processing. The integrated circuit 100 includes a substrate 102. The substrate 102 may be a semiconductor substrate, such as a bulk semiconductor, or the like, which may be doped (e.g., with a P-type or an N-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. In the example of FIG. 1 the semiconductor stack 103 includes three semiconductor layers 104 and three sacrificial semiconductor layers 106. However, in practice, different numbers of semiconductor layers 104 and sacrificial semiconductor layers 106 can be utilized without departing from the scope of the present disclosure.

As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures.

In some embodiments, the semiconductor layers 104 may be formed of a first semiconductor material suitable, such as silicon, silicon carbide, or the like, and the sacrificial semiconductor layers 106 may be formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below.

In one example, the semiconductor layers 104 are silicon and the sacrificial semiconductor layers 106 are silicon germanium. In some embodiments, the sacrificial semiconductor layers 106 have a concentration of germanium between 10% and 50%, though other concentrations can be utilized without departing from the scope of the present disclosure. This enables the sacrificial semiconductor layers 106 to be selectively etchable with respect to the semiconductor layers 104. Other materials and concentrations can be utilized without departing from the scope of the present disclosure.

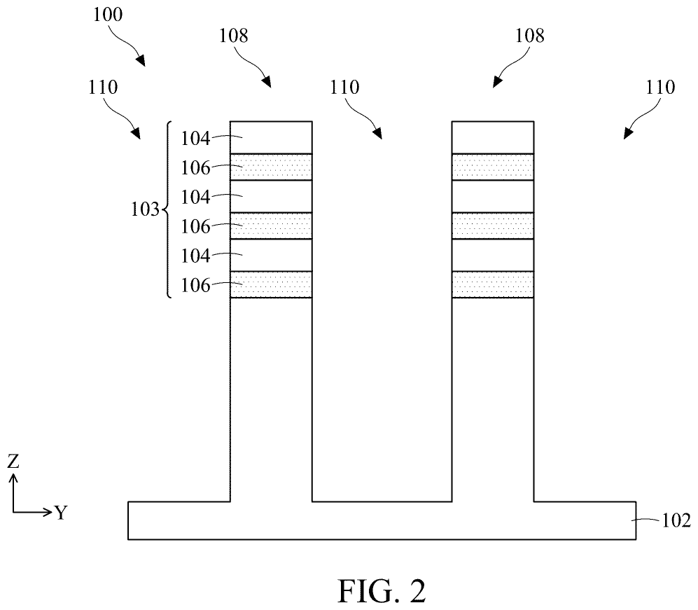

In FIG. 2, a plurality of semiconductor fins 108 have been formed from the semiconductor stack 103. The semiconductor fins 108 are formed by forming trenches 110 in the semiconductor stack 103 and in the substrate 102. Though not shown in FIG. 1, a hard mask layer is first formed and patterned on the semiconductor stack 103. The trenches 110 can be formed with an anisotropic etching process that etches in the downward direction in the presence of the patterned hard mask. The etching process defines semiconductor fins 108 by forming trenches 110 through the sacrificial semiconductor layers 106, the semiconductor layers 104, and the substrate 102.

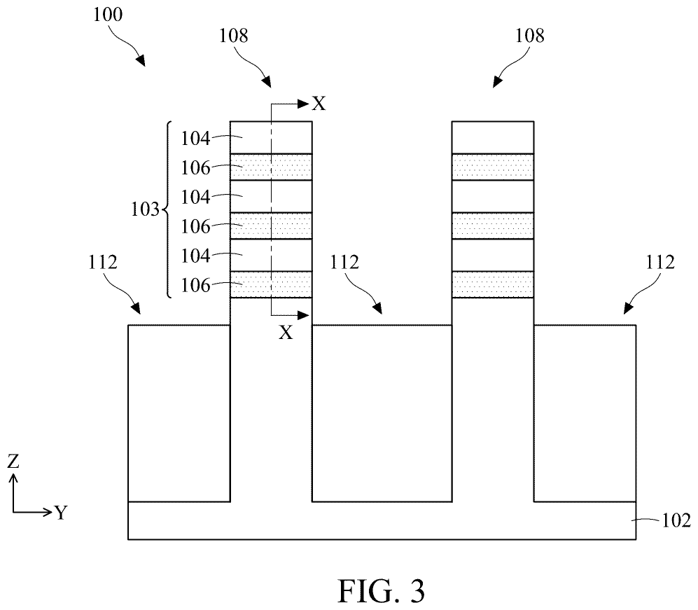

In FIG. 3, shallow trench isolation regions 112 have been formed by depositing a dielectric material in the trenches 110 between fins 108. FIG. 3 illustrates the shallow trench isolation regions 112 as a single layer material. The shallow trench isolation regions 112 may be deposited by chemical vapor deposition (CVD), atomic layer deposition (ALD), physical vapor deposition (PVD), or other suitable deposition processes. In an exemplary embodiment, the dielectric material includes silicon oxide. However, the dielectric material can include SiN, SiCN, SiOC, SiOCN, or other dielectric materials without departing from the scope of the present disclosure.

After deposition of the dielectric material of the shallow trench isolation region 112, an etch-back process has been performed to recess the top of the shallow trench isolation regions 112 below the lowest sacrificial semiconductor layers 106. Other processes can be utilized to form the shallow trench isolation regions 112 without departing from the scope of the present disclosure.

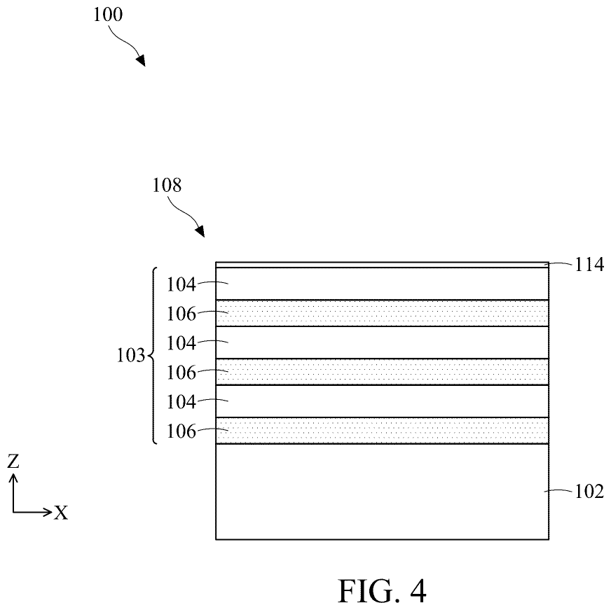

FIG. 4 is an X-view of the integrated circuit 100 taken along cut lines X in FIG. 3, in accordance with some embodiments. Accordingly, FIG. 4, and subsequent Figures correspond to a cross-section through a semiconductor fin 108. In FIG. 4, a dielectric layer 114 has been formed on the semiconductor stack 103. In particular, the dielectric layer 114 has been formed on a top surface of a top semiconductor layer 104. The dielectric layer 114 can include SiO, SiN, SiON, SiCN, SiOC, SiOCN, or other suitable dielectric materials. In a particular example given herein, the dielectric layer 114 includes silicon oxide. The dielectric layer 114 can be deposited by CVD, ALD, PVD, or other suitable dielectric processes. As will be set forth in more detail below, the dielectric layer 114 will eventually be patterned to form a bottom layer of a plurality of sacrificial gate structures.

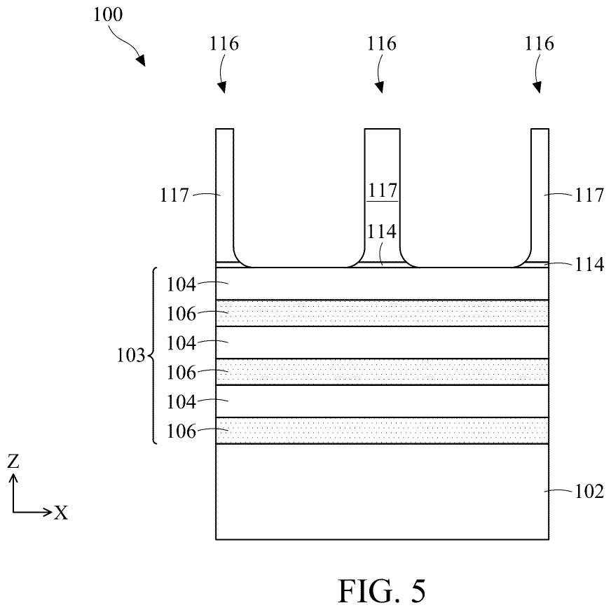

In FIG. 5, sacrificial gate structures 116 have been formed over the fins 108. The sacrificial gate structures 116 each extend parallel to each other in the Y direction. Though not apparent in FIG. 5, the sacrificial gate structures 116 also extend over the fins 108 and the shallow trench isolation regions 112.

The sacrificial gate structures 116 each include a remaining portion of the dielectric layer 114. The sacrificial gate structures include a sacrificial gate layer 117 on the dielectric layer 114. The sacrificial gate layer 117 can include materials that have a high etch selectivity with respect to the shallow trench isolation regions 112. In an exemplary embodiment, sacrificial gate layer 117 includes polysilicon. However, the sacrificial gate layer 117 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 117 may be deposited by physical vapor deposition (PVD), CVD, sputter deposition, or other techniques for depositing the selected material. Though not shown in FIG. 5, in some embodiments, the sacrificial gate structures 116 may include additional dielectric layers above the sacrificial gate layer 117.

In some embodiments, the sacrificial gate structures 116 performed by depositing the sacrificial gate layer 117 on the dielectric layer 114. The hard mask layer is then formed over the sacrificial gate layer 117 and patterned utilizing a photolithography process. The sacrificial gate layer 117 and the dielectric layer 114 are then patterned in accordance with the pattern of the hard mask.

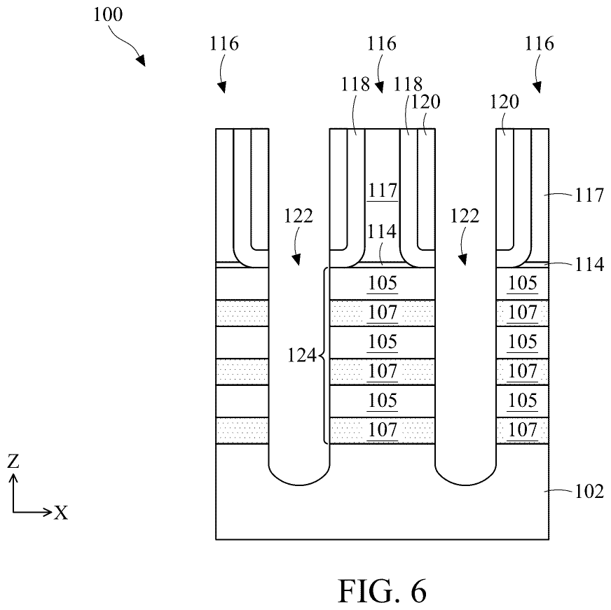

In FIG. 6, dielectric layers 118 and 120 have been formed on the sidewalls of the sacrificial gate structures 116. The dielectric layers 118 and 120 collectively form a gate spacer layer. Accordingly, the dielectric layers 118/120 may be termed a gate spacer layer. Alternatively, in some embodiments, either the dielectric layer 118 or the dielectric layer 120 is a gate spacer layer.

In some embodiments, the dielectric layer 118 is first deposited utilizing CVD, ALD, PVD, or other suitable deposition processes. The dielectric layer 118 can include one or more of SiO, SIN, SiON, SiCN, SiOCN, SiOC, or other suitable dielectric materials. The dielectric layer 120 is the deposited on the dielectric layer 118 utilizing CVD, ALD, PVD, or other suitable deposition processes. The dielectric layer 120 can include one or more of SiO, SiN, SiON, SiCN, SiOCN, SiOC, or other suitable dielectric materials. Following formation of the dielectric layers 118/120, horizontal portions (e.g., in the X-Y plane) of the dielectric layers 118/120 may be removed by an anisotropic etching process, thereby exposing upper surfaces of the fins 108. After patterning of the gate spacer layers, vertically thicker portions of the dielectric layers 118/120 may remain.

In FIG. 6, source/drain trenches 122 have been formed, in accordance with some embodiments. After patterning of the dielectric layers 118/120, one or more etching processes are performed to form source/drain trenches 122 in the fins 108. Forming the source/drain trenches 122 includes etching through each of the semiconductor layers 104, each of the sacrificial semiconductor layers 106, and a portion of the substrate 102. Accordingly, the removal operations may include suitable etch operations for removing materials of the semiconductor layers 104, the sacrificial semiconductor layers 106, and the substrate 102. The etching processes can include reactive ion etching (RIE), neutral beam etching (NBE), atomic layer etching (ALE), or the like.

Formation of the source/drain trenches 122 results in formation of stacks 124 of channels 105. In particular, the remaining portions of the semiconductor layers 104 after formation of the source/drain trenches 122 now correspond to stacked channels 105 of a transistor. Formation of the source/drain trenches 122 results in formation of a plurality of sacrificial semiconductor nanostructures 107 from the sacrificial semiconductor layers 106.

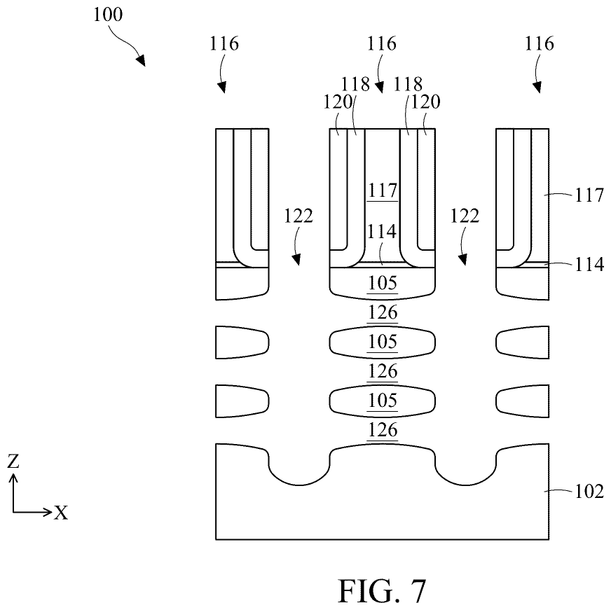

In FIG. 7, an etching process has been performed, in accordance with some embodiments. The etching process completely removes the sacrificial semiconductor nanostructures 107. Accordingly, the etching process can utilize an etchant that selectively etches the material of the sacrificial semiconductor nanostructures 107 relative to other exposed materials, including the material of the substrate 102 and the channels 105. Removal of the sacrificial semiconductor nanostructures 107 results in the formation of gaps 126 between adjacent channels 105.

As will be set forth in more detail below, eventually sacrificial dielectric nanostructures will be formed in place of the sacrificial semiconductor nanostructures 107. Furthermore, source/drain regions will be formed in the source/drain trenches 122. Eventually, gate metals and gate dielectric layers will be formed in place of the sacrificial dielectric nanostructures. The process is utilized to form these structures can result in diffusion of undesired atoms into the channels 105. For example, germanium or oxygen may diffuse into the channels 105, causing undesirable surface roughness, poor charge carrier (electron or hole) mobility, and high density of interface trap(DIT). The interface traps can trap electrons or holes, leading to reduced on-currents. Additionally, dopants such as boron or phosphorus from the source/drain regions can diffuse into the channels 105. This can result in drain induced barrier lowering (DIBL) of the channels 105 and nonuniform heights of the channels 105.

Additionally, the processes utilized to form recesses for inner spacers can generate a “smiling” effect in which end portions of the sacrificial semiconductor nanostructures or sacrificial dielectric nanostructures become highly concave and extend close to the source/drain trenches. When they are eventually replaced with gate metals, this can result in a short circuit between gate metals and source/drain regions. Formation of the recess also can etch the channels 105, thereby increasing parasitic resistances. As will be set forth in more detail below, embodiments of the present disclosure form an interfacial dielectric layer on the exposed portions of the channels 105 to protect against the various drawbacks mentioned above.

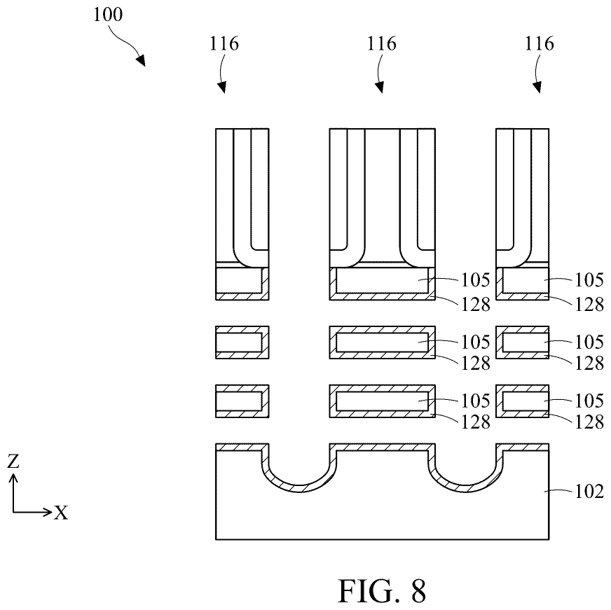

In FIG. 8, an interfacial dielectric layer 128 has been formed on the exposed surfaces of the channels 105. In some embodiments, the interfacial dielectric layer 128 is formed via ALD or CVD such that the interfacial dielectric layer 128 grows on all exposed surfaces of the channels 105 And on exposed surfaces of the substrate 102 (end surfaces, side surfaces, top/bottom surfaces. Only the top surface of the top channel 105 is not covered by the interfacial dielectric layer 128 due to the presence of the sacrificial gate structures 116 and the gate spacer layers.

In some embodiments, the interfacial dielectric layer 128 includes SiOC, SiN, SiOCN, AlOx, HfSiON, or other suitable dielectric materials. In some embodiments, the dielectric layer 128 is doped with fluorine. For example, the interfacial dielectric layer 128 can include SiOCN:F, SiOC:F, SiO:F, or other fluorine doped dielectric materials. The interfacial dielectric layer 128 can be doped with fluorine by introducing fluorine into a deposition chamber with the other deposition materials during an ALD or CVD deposition process. The fluorine is diffused into the channels 105. This can help prevent diffusion of other dopants (such as P-type and N-type dopants) into the channels 105.

In some embodiments, the material of the interfacial dielectric layer 128 is selected so that subsequently formed sacrificial dielectric nanostructures and dielectric inner spacers can be selectively etched with respect to the material of the interfacial dielectric layer 128. Furthermore, in some embodiments, the material of the interfacial dielectric layer 128 is selected to inhibit or prevent diffusion of impurities into the channel. The impurities can include source/drain dopant species, Ge, O, or other dopant species.

In some embodiments, the thickness of the interfacial dielectric layer 128 is less than 1 nm. In some embodiments, the thickness of the interfacial dielectric layer 128 is between 0.1 nm and 1 nm. Such a thickness can be sufficient to prevent diffusion of a multitude species into the channels 105 and to protect the channels 105 from being etched in subsequent processes. Other thicknesses can be utilized without departing from the scope of the present disclosure.

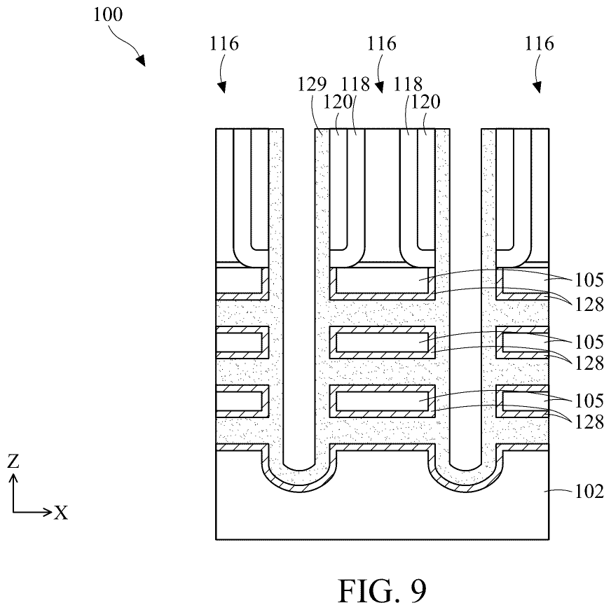

In FIG. 9, a dielectric layer 129 has been deposited, in accordance with some embodiments. The dielectric layer 129 is deposited on exposed surfaces of the dielectric layers 118/120 and on exposed surfaces of the interfacial dielectric layer 128. The dielectric layer 129 is deposited by ALD, CVD, or other suitable deposition processes. The thickness of the dielectric layer 129 is selected to entirely fill the gaps 126 between channels 105. In some embodiments, the dielectric layer 129 includes SiO, SiN, SiON, SiCN, SiOC, SiOCN, or other suitable dielectric materials. In a particular example, the dielectric layer 129 includes silicon oxide. In some embodiments, the material of the dielectric layer 129 is selected to be selectively etchable with respect to the material of the interfacial dielectric layer 128.

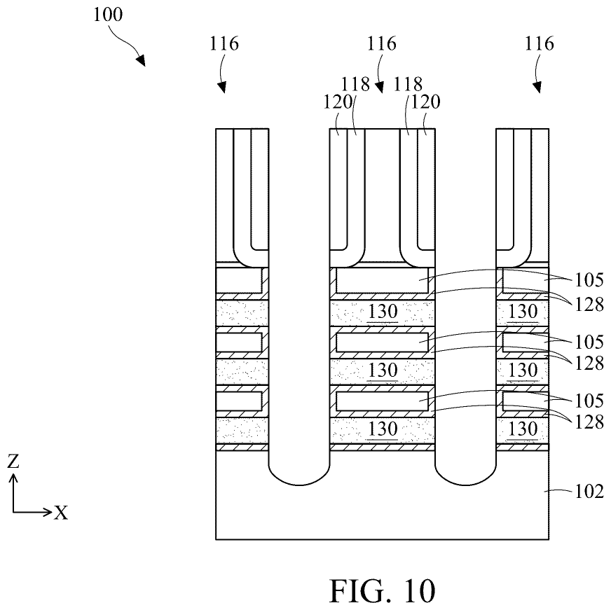

In FIG. 10, sacrificial dielectric nanostructures 130 have been formed in place of the sacrificial semiconductor nanostructures 107, in accordance with some embodiments. More particularly, the sacrificial dielectric nanostructures 130 are formed from the dielectric layer 129. After deposition of the dielectric layer 129, an isotropic etching process is performed to remove the dielectric material from the source/drain trenches 122. The sacrificial gate structures 116, including the gate spacer layers 118/120, act as a mask during the etching process. The dielectric material is removed from all locations not directly below the sacrificial gate structures 116 and the gate spacer layers 118/120 and the interfacial dielectric layer 128. The etching process results in formation of the sacrificial dielectric nanostructures 130 from the dielectric layer 129. The sacrificial dielectric nanostructures 130 may also be termed disposable oxide interposers (DOI), in accordance with some embodiments.

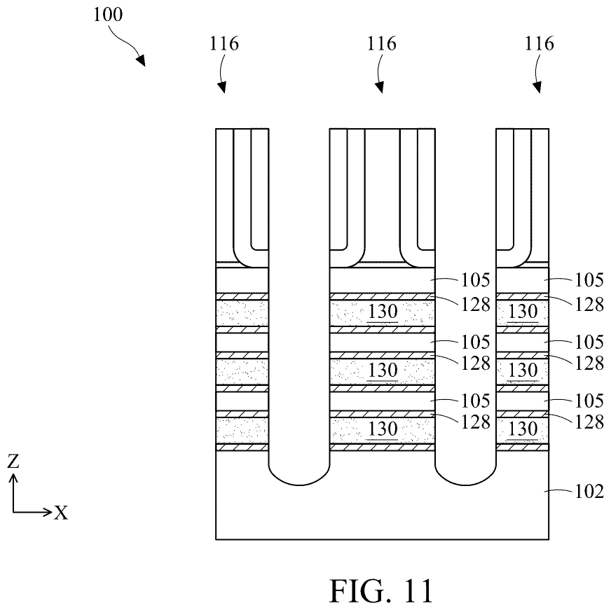

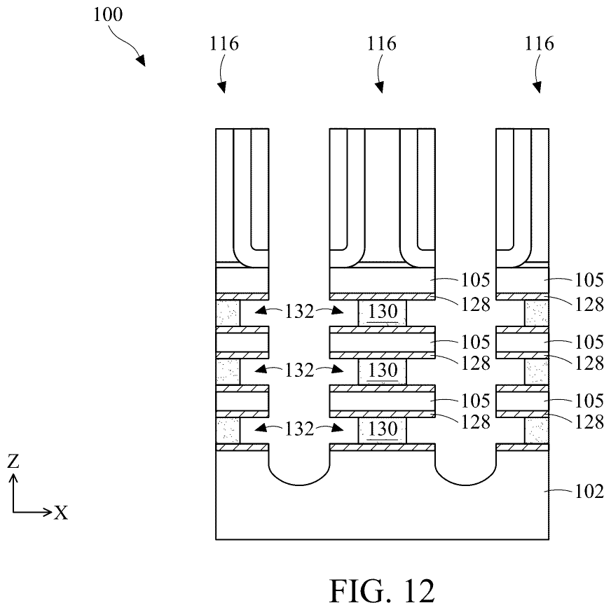

In FIG. 11, an etching process has been performed to remove the interfacial dielectric layer 128 from ends of the channels 105. In this process, the sacrificial gate structures 116, including the dielectric layers 118/120, act as a mask for etching the interfacial dielectric layer 128. The etching process etches selectively in the downward direction and removes the interfacial dielectric layer 128 from sidewalls of the source/drain trenches 122 and from exposed surfaces of the substrate 102. The lateral ends of the channels 105 are exposed.

In FIG. 12, a selective etching process is performed to recess exposed end portions of the sacrificial dielectric nanostructures 130 without substantially etching the channels 105 or the interfacial dielectric layer 128. More particularly, recesses 132 are formed in the sacrificial dielectric nanostructures 130 between adjacent channels 105, or between the lowest channel 105 and the substrate 102. The recesses 132 can be formed by performing an etching process that selectively etches the material of the sacrificial dielectric nanostructures 130 with respect to the material of the channels 105 and the interfacial dielectric layer 128.

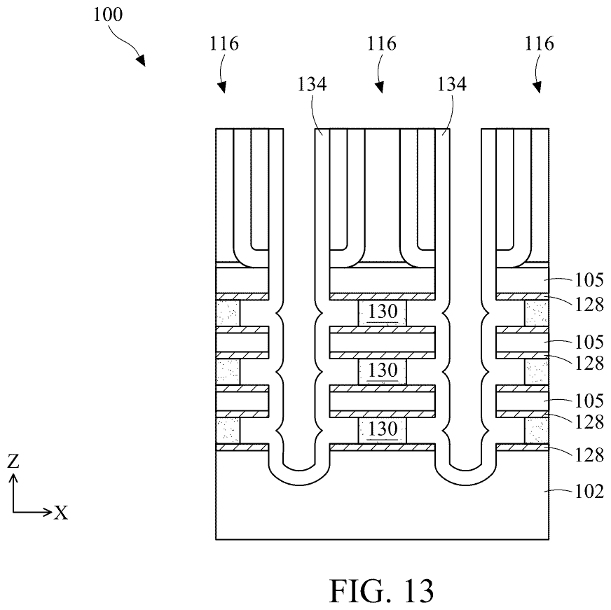

In FIG. 13, a dielectric layer 134 has been deposited, in accordance with some embodiments. The dielectric layer 134 is deposited on exposed surfaces of the dielectric layers 118/120, on exposed surfaces of the interfacial dielectric layer 128, sacrificial dielectric nanostructures 130, all exposed surfaces of the channels 105, and on exposed surfaces of the substrate 102. The dielectric layer 134 is deposited by ALD, CVD, or other suitable deposition processes. The thickness of the dielectric layer 134 is selected to entirely fill the recesses 132 between channels 105. In some embodiments, the dielectric layer 134 includes SiCN, SiOCN, SiON, SiN or other suitable dielectric materials. In some embodiments, the interfacial dielectric layer 128 and the sacrificial dielectric nanostructures 130 can be selectively etched with respect to the material of the dielectric layer 134.

While the shallow trench isolation regions 112 are not present in the view of FIG. 13, the shallow trench isolation regions 112 are protected during the etching process by the dielectric barrier structures 127. As described previously, in some embodiments, the shallow trench isolation regions 112 are a same material as the sacrificial dielectric nanostructures 130. Accordingly, if the dielectric barrier structures 127 are not present during the etching process, it is possible that the shallow trench isolation regions 112 would also be etched.

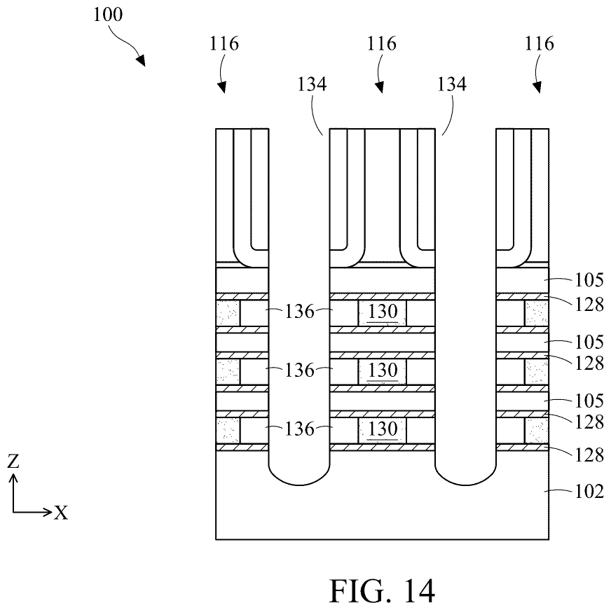

In FIG. 14, inner spacers 136 have also been formed in the recesses 132. The inner spacers 136 are in contact with ends of the sacrificial semiconductor nanostructures 107 and with the channels 105. As will be set forth in further detail below, the inner spacers 136 separate gate metals from source/drain regions. The inner spacers 136 are formed from the dielectric layer 134. In particular, an isotropic etching process is performed to remove the dielectric layer 134 from the trenches 122. The remaining portion of the dielectric layer 134 corresponds to the inner spacers 136.

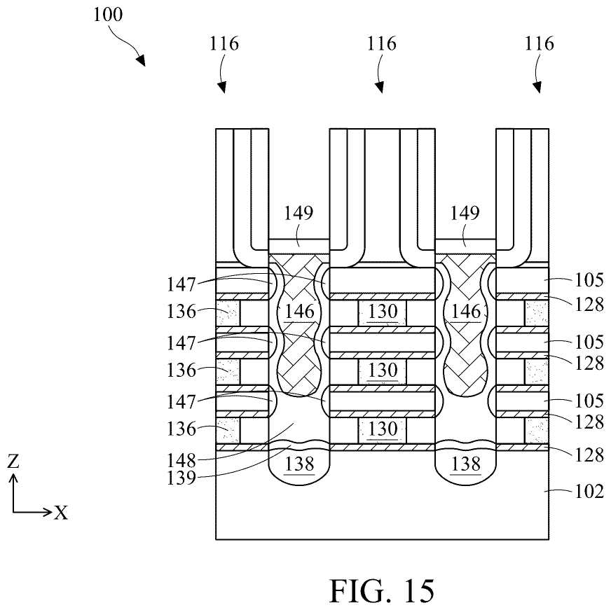

In FIG. 15, a bottom semiconductor layer 138 has been formed in the bottom of the source/drain trenches in contact with the substrate 102. In some embodiments, the bottom semiconductor layer 138 is an intrinsic semiconductor material epitaxially grown from the substrate 102. Other semiconductor materials can be utilized without departing from the scope of the present disclosure. In FIG. 15, bottom dielectric structures 139 have been formed on the bottom semiconductor layer 138, in accordance with some embodiments. The bottom dielectric structures 139 can be formed by PVD, CVD, ALD, or other suitable deposition processes. The bottom dielectric structures 138 can include SiO, SiN, SiON, SiCN, SiOC, SiOCN, or other suitable dielectric materials. In some embodiments, the bottom dielectric structures 139 are instead semiconductor structures. For example, the semiconductor structures can include an intrinsic semiconductor such as silicon, silicon germanium, or other materials. In other words, the semiconductor structure can include undoped (or unintentional doped) Silicon, Silicon Germanium or other materials.

In FIG. 15, a semiconductor layer 147 has been formed on end portions of the channels 105. The semiconductor layer 147 can be part of the source/drain region 146 (described below) and may include a doped semiconductor material or an intrinsic semiconductor material. The semiconductor layer 147 may be formed with an epitaxial growth process.

In FIG. 15, source/drain regions 146 have been formed in the source/drain trenches 122, in accordance with some embodiments. The source/drain regions 146 are epitaxially grown from the channels 105. The source/drain regions 146 are grown on exposed portions of the fins 108 and contact the channels 105. For each stack 124 of channels 105, there are two source/drain regions 146. Some stacks 124 of channels 105 may share a source/drain region 146 with a stack 124 of channels 105 that is adjacent in the X direction.

The source/drain regions 146 may include any acceptable semiconductor material, such as appropriate for N-type or P-type devices. For N-type transistors, the source/drain regions 146 include materials exerting a tensile strain in the channel regions, such as silicon, SiC, SiCP, SiP, or the like, in some embodiments. For P-type transistors, the source/drain regions 146 include materials exerting a compressive strain in the channel regions, such as SiGe, SiGeB, Ge, GeSn, or the like, in accordance with some embodiments. The source/drain regions 146 may have surfaces raised from respective surfaces of the fins and may have facets. Neighboring source/drain regions 146 may merge in some embodiments to form a singular source/drain region 146 over two neighboring fins 108.

In some embodiments, an in-situ doping process may be performed during formation of the source/drain regions 146 to implant to the source/drain regions 146 with N-type dopants or P-type dopants, depending on the conductivity type of the transistor or region being formed. The N-type dopants can include phosphorus, arsenic, antimony, or other suitable N-type dopants species. The P-type dopants can include boron, gallium, indium, or other suitable P-type dopants species. The source/drain regions 146 may be implanted with dopants followed by an annealing process. The source/drain regions 146 may have an impurity concentration of between about 10¹⁹ cm⁻³ and about 10²¹cm⁻³.

In some embodiments, the source/drain regions 146 include multiple semiconductor layers. For example, the semiconductor layer 147 may first be grown from exposed end portions of the channels 105. Subsequently, a second semiconductor layer 148 may be epitaxially grown from the first semiconductor layer 147. Subsequently, a third semiconductor layer (corresponding to the remainder filling portion of the source/drain region 146) may be grown to entirely fill the source/drain trenches 122. The source/drain regions 146 can be formed using different layers or different numbers of layers without departing from the scope of the present disclosure.

In FIG. 15, a silicide 149 is formed on a top surface of the source/drain regions 146. Formation of the silicide 149 can include a metal such as titanium, nickel, tantalum, or other suitable metals. The thermal annealing process is then performed to form the silicide 149 from the metal layer and the semiconductor material of the source/drain regions 146.

As described previously, without the presence of the interfacial dielectric layer 128, it is possible that undesired atoms or molecules can diffuse into the channels 105. For example, oxygen or germanium (or other materials) from the sacrificial dielectric nanostructures 130 or the sacrificial semiconductor nanostructures 107 can diffuse into the channels 105. Furthermore, dopant species from the source/drain regions 146 can also diffuse into the channels 105. However, the presence of the interfacial dielectric layer 128 reduces or prevents diffusion of unwanted atoms into the channels 105.

In some embodiments, as described previously, fluorine is diffused into the channels 105. This can further inhibit diffusion of unwanted dopants into the channels 105. This can result in improved at selected delete and improved carrier mobility of the channels 105.

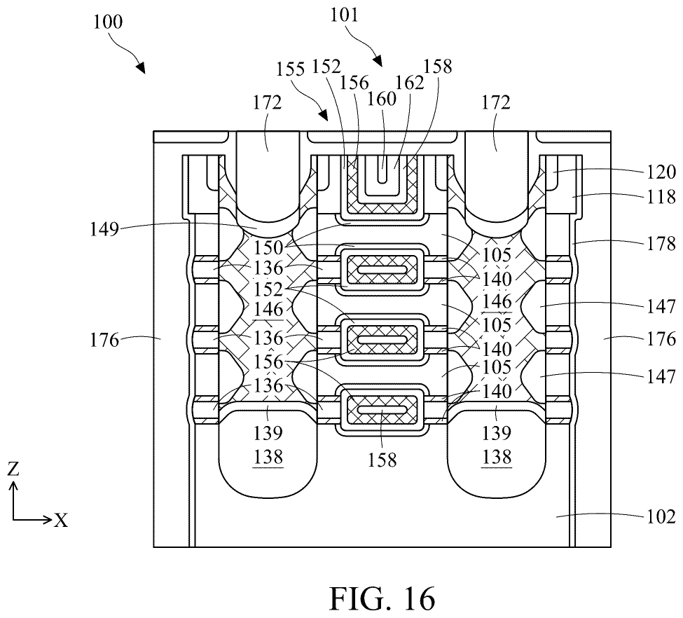

In FIG. 16, the sacrificial gate layer 117 has been removed, in accordance with some embodiments. The sacrificial gate layer 117 can be removed by an etching process that selectively etches the material of the sacrificial gate layer 117 with respect to adjacent materials, such as the dielectric layer 114 and the dielectric layers 118/120. Removal of the sacrificial gate layer 117 results in gate trenches between the dielectric layers 118/120.

In FIG. 16, an etching process has been performed to remove the sacrificial dielectric nanostructures 130, in accordance with some embodiments. The sacrificial dielectric nanostructures 130 can be removed by a selective etching process using an etchant that is selective to the material of the channels interfacial dielectric layer 128, such that the sacrificial dielectric nanostructures 130 are removed without substantially etching the interfacial dielectric layer 128. Thus, the interfacial dielectric layer 128 protects the channels from being etched during removal of the sacrificial dielectric nanostructures 130.

After removal of the sacrificial dielectric nanostructures 130, an etching process is performed to remove exposed portions of the interfacial dielectric layer 128 at the center portions of the channels 105. This patterning of the interfacial dielectric layer 128 results in formation of interfacial dielectric structures 140 from the interfacial dielectric layer 128. Accordingly, the interfacial dielectric structures 140 corresponds to remnants of the interfacial dielectric layer 128. The etching process for removing the interfacial dielectric layer 128 selectively etches the material of the interfacial dielectric layer 128 respect to the material of the channels 105, such that the channels 105 are not substantially etched by removal of the portions of the interfacial dielectric layer 128.

The interfacial dielectric structures 140 still remain between the channels and the inner spacers 136. Because the interfacial dielectric structures 140 are not removed during removal of the sacrificial dielectric nanostructures 130, the possibility of short circuit between subsequently deposited gate metals and the source/drain regions 146 is greatly reduced.

In FIG. 16, a gate dielectric has been formed after removal of the sacrificial dielectric nanostructures 130 and after patterning of the interfacial dielectric layer 128, in accordance with some embodiments. The gate dielectric includes an interfacial gate dielectric layer 150 and a high-K gate dielectric layer 152. The interfacial gate dielectric layer 150 has been deposited on exposed portions of the channels 105, in accordance with some embodiments. The interfacial gate dielectric layer 150 forms directly on the exposed portions of the channels 105. The high-K gate dielectric layer 152 forms on the interfacial gate dielectric layer 150 and on other exposed surfaces, such as the exposed sidewalls of the dielectric layers 118/120, and the inner spacers 136.

The interfacial gate dielectric layer 150 is wrapped around the channels 105. The interfacial gate dielectric layer 150 can include a dielectric material such as silicon oxide, silicon nitride, or other suitable dielectric materials. The interfacial gate dielectric layer 150 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 150 can be formed by a thermal oxidation process, a chemical vapor deposition (CVD) process, or an atomic layer deposition (ALD) process. The interfacial gate dielectric layer 150 can have a thickness between 0.5 nm and 2 nm. Other materials, deposition processes, and thicknesses can be utilized for the interfacial gate dielectric layer 150 without departing from the scope of the present disclosure.

The high-K gate dielectric layer 152 is deposited in a conformal deposition process. The conformal deposition process deposits the high-K gate dielectric layer 152 on the interfacial gate dielectric layer 150, on the substrate 102, and on the dielectric layer 118. The high-K gate dielectric layer 152 is wrapped around the channels 105. The high-K gate dielectric layer 152 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 152 may be formed by CVD, ALD, or any suitable method. Other thicknesses, deposition processes, and materials can be utilized for the high-K gate dielectric layer 152 without departing from the scope of the present disclosure. In some embodiments, both the interfacial gate dielectric layer 150 and the high-K gate dielectric layer 152 are in contact with the interfacial dielectric layer 128.

In FIG. 16, a gate electrode 155 has been deposited, in accordance with some embodiments. The gate electrode 155 is deposited in place of the sacrificial gate layer 117 and the sacrificial dielectric nanostructures 130. Accordingly, the gate electrode 155 is positioned in the gate trench above the interfacial gate dielectric layer 150 and the high-K gate dielectric layer 152. The gate electrode 155 is also wrapped around the channels 105.

In FIG. 16, the gate electrode 155 includes a plurality of gate metals 156, 158, 160, and 162. The gate metals 156 and 158 wrap around the channels 105 and entirely fill the remaining space between the channels 105. However, in some embodiments, depending on the spacing between channels 105 and the thickness of the gate metals, more or fewer of the gate metals may wrap around the channels 105. All of the gate metals 156, 158, 160, and 162 are present in place of the sacrificial gate layer 117 above the highest channel 105. The gate metals 156, 158, and 160, and 162 can include one or more of liner layers, glue layers, work function layers, and gate fill layers. The gate metals 156, 158, 160, and 162 can include or more of Ti, TiN, Ta, TaN, Al, Cu, Co, Ru, W, Au, or other suitable metals. The gate metals 156, 158, 160, and 162 can be deposited by CVD, PVD, ALD, or other suitable deposition processes.

In FIG. 16, a single gate electrode 155 is illustrated as a gate electrode of a transistor 101. However, in practice, the gate electrode 155 can include multiple gate metals. For example, the gate electrode 155 can include one or more liner layers, one or more work function layers, and a gate fill material that fills the remaining spaces between the gate spacer layers 118/120. The gate electrode 155 can include one or more of Ti, TiN, Ta, TaN, Al, Cu, Co, Ru, W, Au, or other suitable conductive materials. The gate electrode 155 can be deposited by PVD, ALD, or CVD.

In FIG. 16, source/drain contacts 172 have been formed on the silicide 149, in accordance with some embodiments. The source/drain contacts 172 include metals that are electrically connected to the source/drain regions 146 by the silicide 149. The source/drain contacts 172 can include W, Al, Au, Ru, Co, Mb, Ta, Ti, TaN, TiN, or other suitable materials.

In FIG. 16, processing of the transistors 101 the substantially complete. Each transistor includes a plurality of channels 105 extending between adjacent source/drain regions 146. Gate dielectric layers 150/152 wrap around the channels 105. One or more gate metals of a gate electrode 155 wrapped around the channels 105 separated from the channels 105 by the gate dielectric layers 150/152. Inner spacers 136 electrically isolate the source/drain regions 146 and the gate metals of the gate electrode 155. As described previously, the presence of the interfacial dielectric layer 128 helps ensure electrical isolation between the gate electrode 155 and the source/drain regions 146.

In FIG. 16, the dielectric structures have been formed including the dielectric layers 176 and 178. The dielectric layers 176 and 178 can include one or more of SiO, SiN, SiON, SiCN, SiOC, SiOCN, or other suitable dielectric materials.

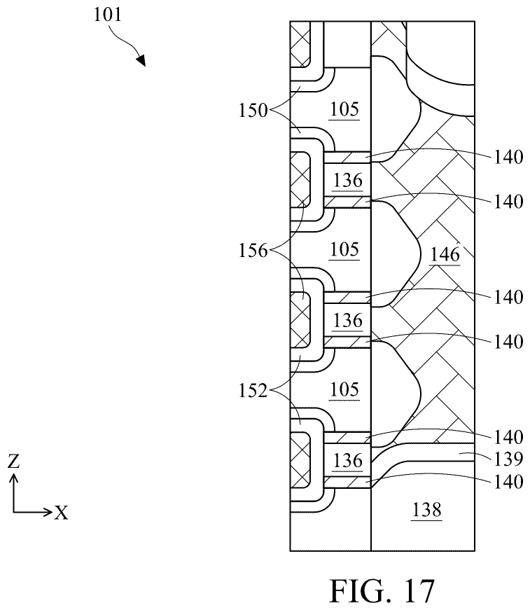

FIG. 17 is an enlarged view of a portion of the transistor 101 of FIG. 16, in accordance with some embodiments. FIG. 17 illustrates the channels 105 separated from each other by inner spacers 136. Furthermore, the interfacial dielectric structures 140 are positioned between the inner spacers 136 and the channels 105. Accordingly, the interfacial dielectric structures 140 are interleaved with the channels 105 and the inner spacers 136. In some embodiments, the interfacial dielectric structures 140 have a thickness less than 1 nm and can be grown by ALD, CVD, or a gas treatment.

In some embodiments, the inner spacers 136 have an inner thickness between 4 nm and 8 nm. In some embodiments, the inner spacers 136 have an outer thickness that is thicker than the inner thickness by less than 0.4 nm. In other words, the portion of the inner spacer 136 that is closest to the gate metal is vertically thinner than the portion of the inner spacer 136 that is closest to the source/drain region. This difference in thickness is less than 0.4 nm. The inner spacer side smiling is less than 0.5 nm. The inner spacers 136 can have a thickness between 4 nm and 8 nm. The thickness of the inner spacers can be between 3 nm and 5 nm. Other thicknesses can be utilized without departing from the scope of the present disclosure.

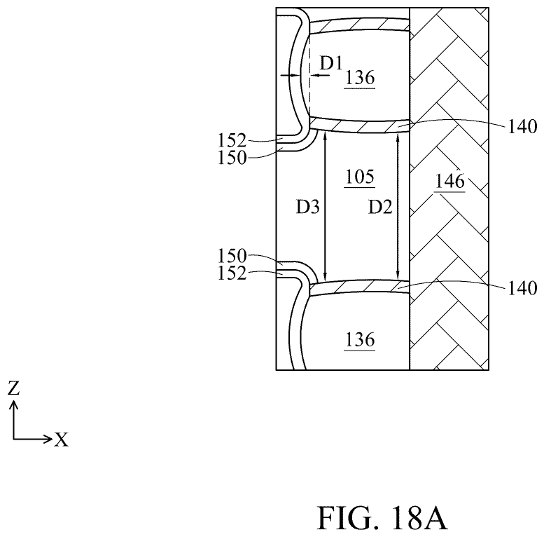

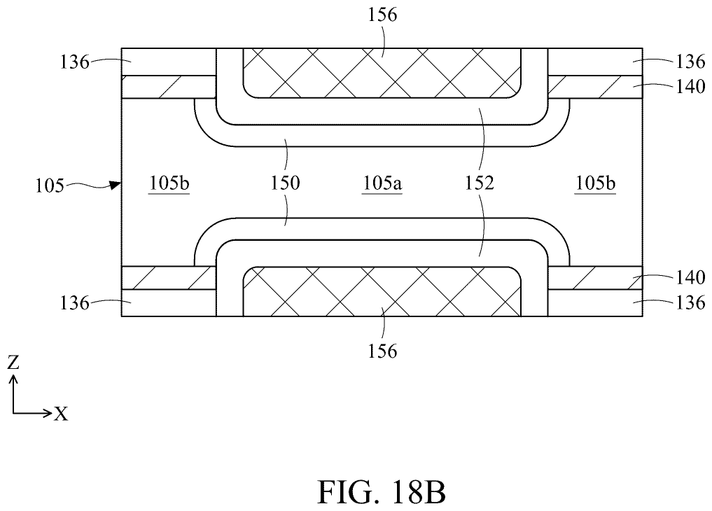

FIG. 18A is an enlarged cross-sectional view of a portion of the transistor 101 of FIG. 17, in accordance with some embodiments. FIG. 18A helps to illustrate the concept of smiling. As can be seen in FIG. 18A, the inner spacer 136 has a convex end abutting the high-K gate dielectric layer 152. In particular, the convex portion has a maximum lateral dimension D1, corresponding to the side smiling of the inner spacer 136. In some embodiments, the dimension D1 is less than 0.5 nm.

FIG. 18A also illustrates that the end portion of the channel 105 has an outer thickness dimension D2 and an outer thickness dimension D3. In some embodiments, D3 is between 5 nm and 8 nm. In some embodiments, D3 is greater than D2 by value less than 0.5 nm.

FIG. 18B is an enlarged cross-sectional view of a portions of the transistor 101 of FIG. 17, in accordance with some embodiments. FIG. 18B illustrates a middle portion 105a of a channel 105 and end portions 105b of the channel 105.

In some embodiments, end portions 105b of the channels 105 have a thickness between 5 nm and 8 nm. In some embodiments, end portions 105b of the channel 105 are thicker than the middle portion 105 a of the channel 105 by less than 0.4 nm. In some embodiments, the inner spacers have a middle width in the X direction between 3 nm and 5 nm. Other values and dimensions can be utilized without departing from the scope of the present disclosure.

In some embodiments, the channels 105 of a stack have a height range less than 0.3 nm. In other words, each of the channels 105 of a stack 124 has a height that is within 0.5 nm of the other channels 105 of the stack 124. In some embodiments, each individual channel 105 has a height range that is less than 0.3 nm, apart from the difference between the middle portion 105a of a channel 105. The height range corresponds to the vertical thickness at various locations on the channel 105. The channels of N-type transistors and the channels of P-type transistors have a height difference that is less than 0.3 nm. In some embodiments, the center channel height is between 3 nm and 6 nm. In the view of FIG. 18, the middle portion of the channel 105 a corresponds to the portion of the channel 105 that is directly above/below the gate metal 156, rather than the end portions 105b that are directly above/below the inner spacers 136. In some embodiments, the space between adjacent channels 105 is between 7 nm and 11. Other dimensions can be utilized without departing from the scope of the present disclosure. In some embodiments, the channels 105 are undoped, such that P-type and N-type dopants are not present in the channels 105. In some embodiments, the channels 105 include fluorine.

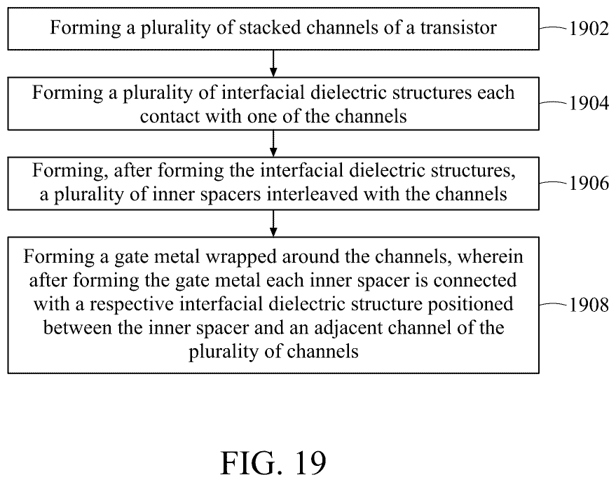

FIG. 19 is a flow diagram of a method 1900 for forming an integrated circuit, in accordance with some embodiments. The method 1900 can utilize the structures, processes, and systems described in relation to FIGS. 1-18B. At 1902, the method includes forming a plurality of stacked channels of a transistor. One example of stacked channels are the channels 105 of FIG. 16. At 1904, the method 1900 includes forming a plurality of interfacial dielectric structures each in contact with one of the channels. One example of interfacial dielectric structures are the interfacial dielectric structures 140 of FIG. 16. At 1906, the method 1900 includes forming, after forming the interfacial dielectric structures, a plurality of inner spacers interleaved with the channels. One example of inner spacers are the inner spacers 136 of FIG. 16. At 1908, the method 1900 includes forming a gate metal wrapped around the channels, wherein after forming the gate metal each inner spacer is connected with a respective interfacial dielectric structure positioned between the inner spacer and an adjacent channel of the plurality of channels. One example of a gate metal is the gate metal 156 of FIG. 16.

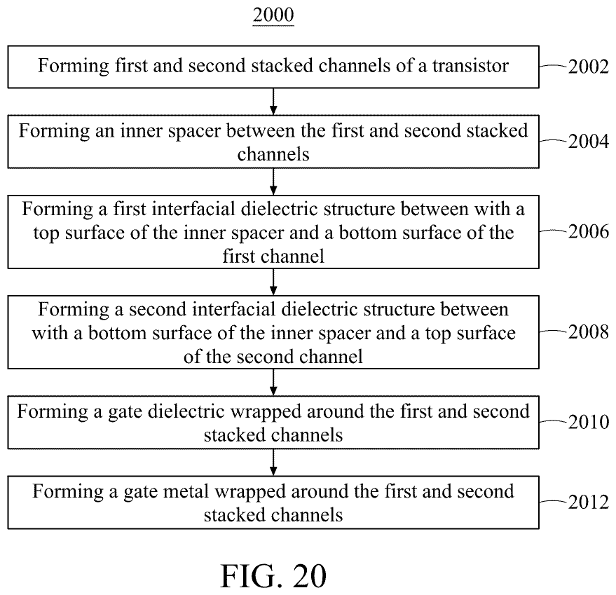

FIG. 20 is a flow diagram of a method 2000 for forming an integrated circuit, in accordance with some embodiments. The method 2000 can utilize the structures, processes, and systems described in relation to FIGS. 1-18B. At 2002, the method 2000 includes forming first and second stacked channels of a transistor. One example of first and second stacked channels are the upper two channels 105 of FIG. 16. At 2004, the method 2000 includes forming an inner spacer between the first and second stacked channels. One example of an inner spacer is the left inner spacer 136 between the upper two channels 105 of FIG. 16. At 2006, the method 2000 includes forming a first interfacial dielectric structure between with a top surface of the inner spacer and a bottom surface of the first channel. One example of a first interfacial dielectric structure is the interfacial dielectric structure 140 and the upper channel 105. At 2008, the method 2000 includes forming a second interfacial dielectric structure in contact with a bottom surface of the inner spacer and a top surface of the second channel. One example of a second interfacial dielectric structure is the interfacial dielectric structure 140 on the bottom surface of the inner spacer and on the top surface of the second channel 105. At 2010, the method 2000 includes forming a gate dielectric wrapped around the first and second stacked channels. One example of a gate dielectric is the gate dielectric layer 152 of FIG. 16. At 2012, the method 2000 includes forming a gate metal wrapped around the first and second stacked channels. One example of a gate metal is the gate metal 156 of FIG. 16.

Embodiments of the disclosure provide a method for forming nanostructure transistors with reduced damage to the nanostructures/channels of the transistors during final release of the channels. The stacked channels of nanostructure transistors are initially interleaved with sacrificial semiconductor nanostructures. After formation of source/drain trenches, the sacrificial semiconductor nanostructures are removed and replaced with sacrificial dielectric nanostructures, also termed disposable oxide interposers. Embodiments of the present disclosure form an interfacial dielectric layer on the exposed channels after removal of the sacrificial semiconductor nanostructures and prior to formation of the sacrificial dielectric nanostructures. Eventually, the sacrificial dielectric nanostructures and the central portions of the interfacial dielectric layer are removed and replaced with gate metals/gate dielectrics. However, in the intervening time, the interfacial dielectric layer helps protect the channels from diffusion of unwanted atoms such as germanium, oxygen, source/drain dopants. Furthermore, the presence of the interfacial dielectric layer helps prevent shorting between gate metals and source/drain regions and the formation of the parasitic resistances.

Usage of the interfacial dielectric layer results in channels with reduced surface roughness, improved mobility, and reduced impurities. Usage of the interfacial dielectric structures results in channels with reduced resistance an improvement in Rp, which corresponds to the total resistance minus the channel resistance. Usage of the interfacial dielectric layer results in reduced risk of short circuits between gate metals and source/drain regions and reduction in parasitic resistance. This further results in transistors having superior electrical characteristics and better overall performance. This can improve wafer yields and overall function of integrated circuits and electronic devices in which the integrated circuits are embedded.

In some embodiments, a method includes forming a plurality of stacked channels of a transistor and forming a plurality of interfacial dielectric structures each in contact with one of the channels. The method includes forming a plurality of inner spacers interleaved with the channels and forming a gate metal wrapped around the channels. After forming the gate metal each inner spacer is in contact with a respective interfacial dielectric structure positioned between the inner spacer and an adjacent channel of the plurality of channels

In some embodiments, a method includes forming first and second stacked channels of a transistor and forming an inner spacer between the first and second stacked channels. The method includes forming a first interfacial dielectric structure in contact with a top surface of the inner spacer and a bottom surface of the first channel and forming a second interfacial dielectric structure in contact with a bottom surface of the inner spacer and a top surface of the second channel. The method includes forming a gate dielectric wrapped around the first and second stacked channels and forming a gate metal wrapped around the first and second stacked channels.

In some embodiments, an integrated circuit includes a transistor. The transistor includes a plurality of stacked channels, a gate dielectric layer wrapped around and in contact with central portions of the channels, and a gate metal wrapped around the channels and separated from the channels by the gate dielectric layer. The transistor includes a source/drain region connected with each of the channels, a plurality of inner spacers interleaved with end portions of the channels, and a plurality of interfacial dielectric structures each positioned in contact with one of the inner spacers and an adjacent channel. The interfacial dielectric structures are laterally between the gate metal and the source/drain region

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a plurality of stacked channels of a transistor;
forming a plurality of interfacial dielectric structures each in contact with one of the channels;
forming, after forming the interfacial dielectric structures, a plurality of inner spacers interleaved with the channels; and
forming a gate metal wrapped around the channels, wherein after forming the gate metal each inner spacer is connected with a respective interfacial dielectric structure positioned between the inner spacer and an adjacent channel of the plurality of channels.

2. The method of claim 1, comprising:
removing, prior to forming the interfacial dielectric structures, a plurality of sacrificial semiconductor nanostructures interleaved with the channels;
forming an interfacial dielectric layer on surfaces of the channels exposed by removal of the sacrificial semiconductor nanostructures; and
forming the interfacial dielectric structures from the interfacial dielectric layer by patterning the interfacial dielectric layer.

3. The method of claim 2, comprising forming a plurality of sacrificial dielectric nanostructures in place of the sacrificial semiconductor nanostructures after forming the interface dielectric layer and prior to patterning the interfacial dielectric layer.

4. The method of claim 3, comprising:
exposing end surfaces of the channels by removing the interfacial dielectric layer from the end surfaces of the channel; and
forming a source/drain region in contact with the end surfaces of the channel after exposing the end surfaces of the channels.

5. The method of claim 3, comprising:
forming recesses in the sacrificial semiconductor nanostructures, wherein forming the recesses exposes portions of the interfacial dielectric layer; and
forming the inner spacers in the recesses in contact with the interfacial dielectric layer.

6. The method of claim 5, comprising:
removing central portions of the sacrificial dielectric nanostructures after forming the inner spacers;
forming the interfacial dielectric structures from the interfacial dielectric layer by removing central portions of the interfacial dielectric layer exposed by removal of the central portions of the sacrificial dielectric nanostructure; and
forming the gate metal in place of the central portions of the sacrificial dielectric nanostructures.

7. The method of claim 6, comprising:
forming a gate dielectric layer wrapped around the channels in place of the removed central portions of the interfacial dielectric layer; and
forming the gate metal on the gate dielectric layer.

8. The method of claim 7, wherein after forming the gate metal, end portions of the channels in contact with the interfacial dielectric layer are thicker than central portions of the channels in contact with the gate dielectric layer.

9. The method of claim 7, wherein the gate dielectric layer is in contact with the interfacial dielectric layer.

10. The method of claim 5, wherein the interfacial dielectric layer is selectively etchable with respect to the inner spacers and the sacrificial dielectric nanostructures.

11. A device, comprising:
a transistor including:
a plurality of stacked channels;
a gate dielectric layer wrapped around and in contact with central portions of the channels;
a gate metal wrapped around the channels and separated from the channels by the gate dielectric layer;
a plurality of inner spacers interleaved with end portions of the channels;
a source/drain region connected with each of the channels; and
a plurality of interfacial dielectric structures each positioned in contact with one of the inner spacers and an adjacent channel, the interfacial dielectric structures are laterally between the gate metal and the source/drain region.

12. The device of claim 11, wherein one or more of the interfacial dielectric structures is in contact with the source/drain region.

13. The device of claim 11, wherein the gate dielectric layer is in contact with one or more of the interfacial dielectric structures.

14. The device of claim 13, wherein the gate dielectric layer includes an interfacial gate dielectric layer in contact with the channels and a high-K gate dielectric layer in contact with the interfacial gate dielectric layer, wherein the interfacial dielectric structures are in contact with the interfacial gate dielectric layer and the high-K gate dielectric layer.

15. The device of claim 14, wherein the interfacial gate dielectric layer is of a different dielectric material than the interfacial dielectric structures.

16. The device of claim 13, wherein the interfacial gate dielectric structures are selectively etchable with respect to the inner spacers and the interfacial gate dielectric layer.

17. The device of claim 11, wherein a first inner spacer from the plurality of inner spacer includes:
a top surface in contact with a first interfacial dielectric structure of the plurality of interfacial dielectric structures; and
a bottom surface in contact with a second interfacial dielectric structure of the plurality of interfacial dielectric structures.

18. A method, comprising:
forming first and second stacked channels of a transistor;
forming an inner spacer between the first and second stacked channels;
forming a first interfacial dielectric structure between a top surface of the inner spacer and a bottom surface of the first channel;
forming a second interfacial dielectric structure between a bottom surface of the inner spacer and a top surface of the second channel;
forming a gate dielectric wrapped around the first and second stacked channels; and
forming a gate metal wrapped around the first and second stacked channels.

19. The method of claim 18, further comprising forming a source/drain region of the transistor in contact with the first channel, the second channel, the inner spacer, the first interfacial dielectric structure, and the second interfacial dielectric structure.

20. The method of claim 19, wherein the first and second interfacial dielectric structures are selectively etchable with respect to the inner spacer.
